(19) United States
(12) Patent Application Publication
(10) Pub. No.: US 2026/0293561 A1
(43) Pub. Date: Sep. 24, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/250,096

(22) Filed: Jun. 26, 2025

(30) Foreign Application Priority Data
Mar. 20, 2025 (KR) 10-2025-0035714

(51) Int. Cl. H01L 21/78; H01L 23/544; H01L 23/58

(52) U.S. Cl. CPC H10P 54/00; H10W 42/00; H10W 46/00; H10W 46/301

(57) ABSTRACT

A semiconductor device according to an embodiment of the present disclosure may include a substrate including a chip region and a scribe lane region; an insulating structure disposed on the substrate, and having one side surface in the scribe lane region; a barrier structure including an inner barrier layer that has an uppermost surface disposed closer to the substrate than the upper surface of the insulating structure and overlaps with the one side surface of the insulating structure and an outer barrier layer on the inner barrier layer; and a redistribution pattern layer covering the barrier structure, and spaced apart from the inner barrier layer.

### CROSS-REFERENCE TO RELATED APPLICATION

The present application claims priority under 35 U.S.C. § 119(a) to Korean Patent Application No. 10-2025-0035714 filed on Mar. 20, 2025, which is incorporated herein by reference in its entirety.

### BACKGROUND

### 1. Technical Field

Embodiments of the present disclosure relate generally to a semiconductor device, and more particularly, to a semiconductor device.

### 2. Related Art

Semiconductor devices are attracting attention as an important element in the electronics industry due to their characteristics such as miniaturization, multi-functionality and/or low manufacturing cost. As the electronics industry advances, semiconductor devices are increasingly required to be highly integrated.

In order to meet the requirements for high integration, semiconductor devices may include redistribution layer (RDL) patterns. The redistribution layer patterns may be electrically connected to chip pads and may extend from a region where the chip pads are disposed to another region.

### SUMMARY

Objects of embodiments of the disclosure are not limited to those set forth herein, and other unmentioned objects would be apparent to one of ordinary skill in the art from the following description.

Embodiments of the present disclosure are directed to providing a semiconductor device capable of preventing deterioration of device characteristics due to process defects.

In an embodiment of the present disclosure, a semiconductor device may include a substrate including a chip region and a scribe lane region; an insulating structure disposed on the substrate, and having one side surface in the scribe lane region; a barrier structure including an inner barrier layer that has an uppermost surface disposed closer to the substrate than the upper surface of the insulating structure and overlaps with the one side surface of the insulating structure and an outer barrier layer on the inner barrier layer; and a redistribution pattern layer covering the barrier structure, and spaced apart from the inner barrier layer.

In an embodiment of the present disclosure, a semiconductor device may include a substrate; an interlayer insulating layer disposed on the substrate, and including an outer boundary; an insulating structure disposed on the interlayer insulating layer, and including an inner boundary that is disposed inward of the outer boundary; a barrier structure including an inner barrier layer that has an uppermost surface disposed closer to the substrate than the upper surface of the insulating structure and overlaps with one side surface of the insulating structure and an outer barrier layer on the inner barrier layer; and a redistribution pattern layer covering the barrier structure, and spaced apart from the inner barrier layer.

In an embodiment of the present disclosure, a semiconductor device may include an interlayer insulating layer over a substrate; an insulating structure disposed over the interlayer insulating layer, the insulating structure comprising a redistribution insulating layer and a passivation layer; a guard ring passing through the interlayer insulating layer and extending inside the passivation layer over a guard ring region of the substrate; an insulating structure disposed on the substrate, and having one side surface in a scribe lane region of the substrate; a dummy pattern layer having a lower surface that is coplanar with the lower surface of the passivation layer; a barrier structure formed over the dummy pattern layer, and having a middle part extending parallel to the dummy pattern in a first direction and a edge part extending vertically to the dummy pattern layer, and a redistribution pattern layer covering the barrier structure.

According to an embodiment of the present disclosure, it is possible to provide a semiconductor device capable of preventing deterioration of device characteristics due to process defects.

The advantages of the present disclosure are not limited to the foregoing advantages, and other advantages will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a simplified schematic view illustrating a wafer in which semiconductor devices according to an embodiment of the present disclosure are integrated.

FIG. 2 is an enlarged view of a region A of FIG. 1.

FIG. 3 is a simplified schematic view illustrating a cross-sectional structure of a part indicated by a line I-I′ of FIG. 2.

FIG. 4 to FIG. 11 are simplified schematic views illustrating a method of forming a semiconductor device according to an embodiment disclosed in FIG. 3.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the technical concepts of the present disclosure may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

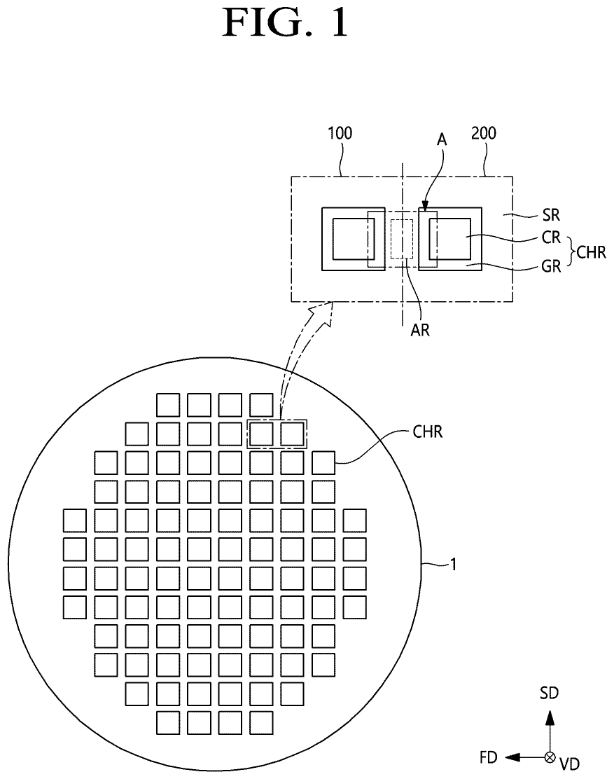

FIG. 1 is a simplified schematic view illustrating a wafer 1 in which semiconductor devices according to an embodiment of the present disclosure are integrated.

Referring to FIG. 1, the wafer 1 may include chip regions CHR and a scribe lane region SR. The scribe region SR may surround the chip regions CHR.

The chip regions CHR may be regions where individual semiconductor chips are formed after the wafer 1 is diced. One or more integrated circuits for functioning as an individual semiconductor chip may exist in each chip region CHR. Each of the chip regions CHR may include a cell region CR and a guard ring region GR. The guard ring region GR may be continuous to the side surfaces of the cell region CR.

The scribe lane region SR may extend in a first direction FD and a second direction SD to surround the side surfaces of each chip region CHR. The first direction FD and the second direction SD may be substantially perpendicular to each other. The scribe lane region SR may be continuous to the chip region CHR. In a dicing process, the wafer 1 may be diced along a cutting line in the scribe lane region SR using a dicing technique such as, for example, laser, blade, etc.

The scribe lane region SR may include a redistribution alignment key region AR. The redistribution alignment key region AR may refer to a region where a redistribution alignment key is disposed. The redistribution alignment key may be used for alignment for etching a redistribution pattern layer in the manufacturing process of a semiconductor device.

The redistribution alignment key region AR may be disposed between neighboring chip regions CHR. Although FIG. 1 illustrates that the redistribution alignment key region AR is disposed between chip regions CHR neighboring each other in the first direction FD, a location where the redistribution alignment key region AR is disposed is not limited thereto.

Referring to FIG. 1, a first semiconductor device 100 and a second semiconductor device 200 neighboring the first semiconductor device 100 may be included in a partial region of the wafer 1. The region between the first semiconductor device 100 and the second semiconductor device 200 may be defined as a region A.

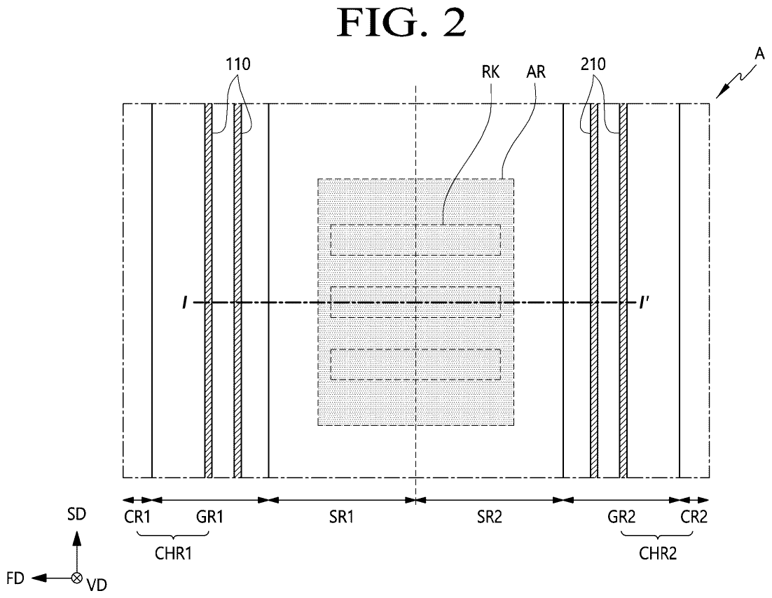

FIG. 2 is an enlarged view of the region A of FIG. 1.

A partial region of the first semiconductor device 100 and a partial region of the second semiconductor device 200 may be included in the region A.

Referring to FIG. 2, the first semiconductor device 100 may include parts of a first chip region CHR1 and a first scribe lane region SR1 continuous to the first chip region CHR1. The first chip region CHR1 may include a first cell region CR1 and a first guard ring region GR1. The first guard ring region GR1 may be continuous to the first cell region CR1. The first guard ring region GR1 may include a first guard ring 110. The first guard ring 110 may extend to surround the edges of the first cell region CR1.

Referring to FIG. 2, the second semiconductor device 200 may include parts of a second chip region CHR2 and a second scribe lane region SR2 continuous to the second chip region CHR2. The second chip region CHR2 may include a second cell region CR2 and a second guard ring region GR2. The second guard ring region GR2 may be continuous to the second cell region CR2. The second guard ring region GR2 may include a second guard ring 210. The second guard ring 210 may extend to surround the edges of the second cell region CR2.

The redistribution alignment key region AR may be disposed in partial regions of the first scribe lane region SR1 and the second scribe lane region SR2. A redistribution alignment key RK may be disposed in the redistribution alignment key region AR. The redistribution alignment key RK may be used for alignment for etching a redistribution pattern layer in the manufacturing process of a semiconductor device.

Although, in FIG. 2, three redistribution alignment keys RK are illustrated in the redistribution alignment key region AR, the embodiments are not necessarily limited thereto, and the redistribution alignment key region AR may have various numbers of redistribution alignment keys RK.

In the illustrated embodiment of FIG. 2, the redistribution alignment key RK may be disposed in a bar shape on a plane defined by the first direction FD and the second direction SD as illustrated in FIG. 2, but is not limited thereto. The disposition of the redistribution alignment key RK may be changed in various ways. Also, the shape of the redistribution alignment key RK may be changed.

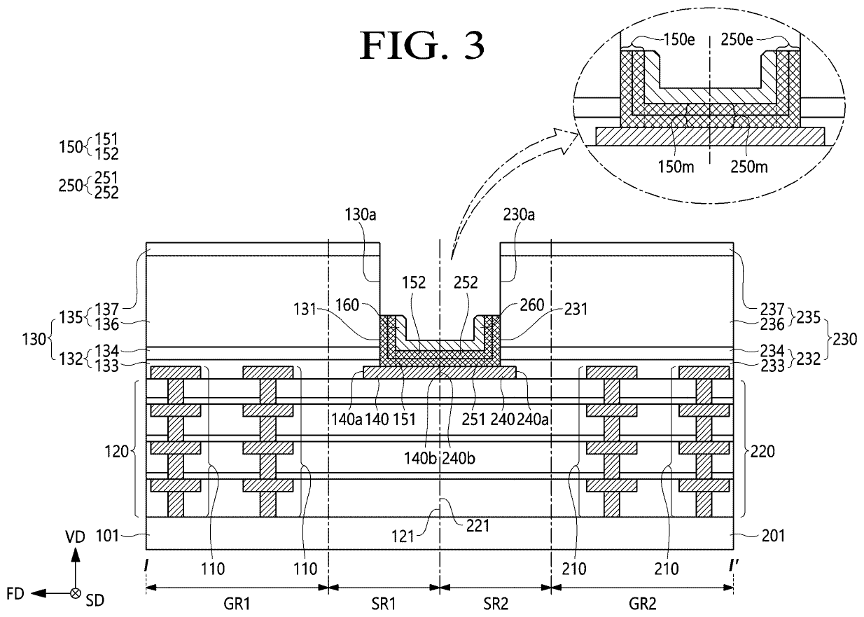

FIG. 3 is a simplified schematic view illustrating a cross-sectional structure of a part indicated by a line I-I′ of FIG. 2.

Referring to FIG. 3, the first semiconductor device 100 may include a first substrate 101, the first guard ring 110, a first interlayer insulating layer 120 over the first substrate, a first insulating structure 130 disposed over the insulating layer 120, a first dummy pattern layer 140, a first barrier structure 150 disposed over the first dummy pattern layer 140, and a first redistribution pattern layer 160 disposed over the first barrier structure. The first guard ring 120 may pass through the insulating layer 120.

The first semiconductor device 100 may include a first outer boundary 121. In an embodiment, the first outer boundary 121 may be a boundary that is disposed outermost among the boundaries of the first semiconductor device 100. In an embodiment, the outer boundary of the first interlayer insulating layer 120 may be the same as the first outer boundary 121. In an embodiment, the first outer boundary 121 may be disposed in the first scribe lane region SR1.

The first insulating structure 130 may include a first inner boundary 131 in the first scribe lane region SR1. The first inner boundary 131 may be a boundary that is closer to the first guard ring region GR1 than the first outer boundary 121 among the boundaries of the first semiconductor device 100. The first insulating structure 130 may have one side surface 130a in the first scribe lane region SR1. In an embodiment, the one side surface 130a of the first insulating structure 130 may be the same as the first inner boundary 131.

The first outer boundary 121 may extend in a third direction VD. The first inner boundary 131 may extend in the third direction VD. The third direction VD may be substantially perpendicular to the first direction FD.

The first substrate 101 may be disposed in the first chip region CHR1 and the first scribe lane region SR1. The first chip region CHR1 may include the first cell region CR1 and the first guard ring region GR1.

The first guard ring 110 and the first interlayer insulating layer 120 may be disposed on the first substrate 101. The first substrate 101 may include a semiconductor substrate such as a silicon wafer or a silicon-on-insulator (SOI) wafer. The first substrate 101 may include a III-V group semiconductor substrate, for example, a compound semiconductor substrate such as GaAs. The first substrate 101 may include monocrystalline silicon, polysilicon, amorphous silicon, monocrystalline silicon germanium, polycrystalline silicon germanium, carbon-doped silicon, or a combination thereof.

The first guard ring 110 may be disposed on the first substrate 101. The first guard ring 110 may be disposed in the first guard ring region GR1. The first guard ring 110 may be disposed inward of the first inner boundary 131. The first guard ring 110 may be disposed inward of the one side surface 130a of the first insulating structure 130. The first guard ring 110 may pass through the first interlayer insulating layer 120 to contact the first substrate 101 at one end thereof. An opposite end of the first guard ring may extend into a first passivation oxide layer 133.

The first interlayer insulating layer 120 may include silicon oxide, silicon nitride, silicon oxynitride, low-k dielectric, high-k dielectric, or a combination thereof. The first interlayer insulating layer 120 may include an insulating material with excellent step coverage and gap fill characteristics. In an embodiment, the first interlayer insulating layer 120 may include oxide such as tetraethyl orthosilicate (TEOS) or borophosphosilicate glass (BPSG).

The first insulating structure 130 may be disposed on the first interlayer insulating layer 120. The first insulating structure 130 may include a first passivation layer 132 and a first redistribution insulating layer 135. The first redistribution insulating layer 135 may be disposed on the first passivation layer 132.

The first passivation layer 132 includes high density plasma oxide, nitride, or a combination thereof. The first passivation layer 132 may include the first passivation oxide layer 133 and the first passivation nitride layer 134. The first passivation nitride layer 134 may be disposed on the first passivation oxide layer 133. In an embodiment, the first passivation oxide layer 133 may include high density plasma oxide.

The first redistribution insulating layer 135 may include silicon oxide, silicon nitride, silicon oxynitride, low-k dielectric, high-k dielectric, or a combination thereof. The first redistribution insulating layer 135 may include a first redistribution oxide layer 136 and a first redistribution nitride layer 137. The first redistribution nitride layer 137 may be disposed on the first redistribution oxide layer 136.

The first dummy pattern layer 140 may be disposed on the first interlayer insulating layer 120. The first dummy pattern layer 140 may form the same plane with the lower surface of the first insulating structure 130. The first dummy pattern layer 140 may overlap with at least a part of the region disposed between the first outer boundary 121 and the first inner boundary 131.

One side surface 140a of the first dummy pattern layer 140 may be disposed inward of the first inner boundary 131. The one side surface 140a of the first dummy pattern layer 140 may be disposed inward of the one side surface 130a of the first insulating structure 130. The other side surface 140b of the first dummy pattern layer 140 may be disposed outward of the first inner boundary 131. The other side surface 140b of the first dummy pattern layer 140 may be disposed outward of the one side surface 130a of the first insulating structure 130.

The first barrier structure 150 may be disposed on the first dummy pattern layer 140. In an embodiment, the first barrier structure 150 may overlap with the first dummy pattern layer 140. The first barrier structure 150 may be disposed on the one side surface 130a of the first insulating structure 130. The first barrier structure 150 (151, 152) may be disposed between the one side surface 130a of the first insulating structure 130 and the other side 140b surface of the first dummy pattern layer 140. The lower surface of the first barrier structure 150 may be spaced apart more from the first substrate 101 than the lower surface of the first insulating structure 130.

Although FIG. 3 illustrates the first barrier structure 150 includes a first middle part 150m extending parallel to the first direction FD and second edge part 150e extending parallel to the third direction VD, however, the embodiments are not limited thereto, and the extending direction or directions of the first barrier structure 150 may be changed in various ways.

The first barrier structure 150 may include a first inner barrier layer 151 and a first outer barrier layer 152. The uppermost surface of the first inner barrier layer 151 may be disposed closer to the first substrate 101 than the upper surface of the first insulating structure 130.

The lower surface of the first passivation layer 132 may be disposed closer to the first substrate 101 than the lower surface of the first inner barrier layer 151. The lower surface of the first inner barrier layer 151 may be disposed between the upper surface of the first passivation layer 132 and the lower surface of the first passivation layer 132.

The distance from the uppermost surface of the first inner barrier layer 151 to the first substrate 101 in a vertical direction may be larger than the distance from the uppermost surface of the first guard ring 110 to the first substrate 101 in the vertical direction. In an embodiment, the vertical direction may refer to the third direction VD.

The first outer barrier layer 152 may be disposed outward of the first inner barrier layer 151 from the one side surface 130a of the first insulating structure 130. The first outer barrier layer 152 may be disposed on the first inner barrier layer 151. The first outer barrier layer 152 may overlap with the first inner barrier layer 151.

The first outer barrier layer 152 may completely cover any one of the side surfaces of the first inner barrier layer 151. In an embodiment, one of the side surfaces of the first inner barrier layer 151 may be spaced apart from the one side surface 130a of the first insulating structure 130. One of the side surfaces of the first inner barrier layer 151 may be disposed between the one side surface 130a of the first insulating structure 130 and the side surface of the first redistribution pattern layer 160. In an embodiment, one of the side surfaces of the first inner barrier layer 151 may be disposed between the first outer boundary 121 and the first inner boundary 131.

Although not illustrated in FIG. 3, in an embodiment, the first outer barrier layer 152 may extend in the third direction VD to cover the uppermost surface of the first inner barrier layer 151.

The first inner barrier layer 151 may include conductive metal nitride such as titanium nitride (TiN), tantalum nitride (TaN) and tungsten nitride (WN). In an embodiment, the first inner barrier layer 151 may include titanium nitride (TiN). In an embodiment, the first outer barrier layer 152 may include the same or substantially the same material as the first inner barrier layer 151.

The first redistribution pattern layer 160 may be disposed on the first barrier structure 150. The first redistribution pattern layer 160 may cover the first barrier structure 150. The first redistribution pattern layer 160 may be spaced apart from the first inner barrier layer 151.

Although not illustrated in FIG. 3, in an embodiment, the first redistribution pattern layer 160 may extend in the third direction VD to cover the uppermost surface of the first barrier structure 150. Although FIG. 3 illustrates that the first redistribution pattern layer 160 has a middle part extending in a direction parallel to the first direction and opposite edge or side parts each extending in the third direction VD, however, the embodiments of the present disclosure are not limited thereto, and the extending direction or directions of the first redistribution pattern layer 160 may be changed in various ways.

The second semiconductor device 200 may include a second substrate 201, the second guard ring 210, a second interlayer insulating layer 220, a second insulating structure 230, a second dummy pattern layer 240, a second barrier structure 250, and a second redistribution pattern layer 260. The above mentioned features of the second semiconductor device 200 may be mirror images of the corresponding features of the first semiconductor device 100 over an axis of symmetry extending along the first outer boundary 121.

The second semiconductor device 200 may include the second outer boundary 221. In an embodiment, the second outer boundary 221 may be a boundary that is disposed outermost among the boundaries of the second semiconductor device 200. In an embodiment, the outer boundary of the second interlayer insulating layer 220 may be the same as the second outer boundary 221. In an embodiment, the second outer boundary 221 may be disposed in the second scribe lane region SR2.

The second insulating structure 230 may include a second inner boundary 231 disposed in the second scribe lane region SR2. The second inner boundary 231 may be a boundary that is closer to the second guard ring region GR2 than the second outer boundary 221 among the boundaries of the second semiconductor device 200. The second insulating structure 230 may have one side surface 230a in the second scribe lane region SR2. In the illustrated embodiment, the one side surface 230a of the second insulating structure 230 may be the same as the second inner boundary 231.

The second outer boundary 221 may extend in the third direction VD. The second inner boundary 231 may extend in the third direction VD.

The second substrate 201 may be disposed in the second chip region CHR2 and the second scribe lane region SR2. The second chip region CHR2 may include the second cell region CR2 and the second guard ring region GR2.

The second guard ring 210 and the second interlayer insulating layer 220 may be disposed on the second substrate 201. The second substrate 201 may include the same or substantially the same material as the first substrate 101.

The second guard ring 210 may be disposed on the second substrate 201. The second guard ring 210 may be disposed in the second guard ring region GR2. The second guard ring 210 may be disposed inward of the second inner boundary 231. The second guard ring 210 may pass through the second interlayer insulating layer 220 to contact the second substrate 201 at one end thereof. The other end of the second guard ring 210 may extend into a second passivation oxide layer 233.

The second interlayer insulating layer 220 may include the same or substantially the same material as the first interlayer insulating layer 120.

The second insulating structure 230 may be disposed on the second interlayer insulating layer 220. The second insulating structure 230 may include a second passivation layer 232 and a second redistribution insulating layer 235. The second redistribution insulating layer 235 may be disposed on the second passivation layer 232.

The second passivation layer 232 may include substantially the same material as the first passivation layer 132. The second passivation layer 232 may include a second passivation oxide layer 233 and a second passivation nitride layer 234. The second passivation nitride layer 234 may be disposed on the second passivation oxide layer 233. In an embodiment, the second passivation oxide layer 233 may include substantially the same material as the first passivation oxide layer 133.

The second redistribution insulating layer 235 may include a second redistribution oxide layer 236 and a second redistribution nitride layer 237. The second redistribution nitride layer 237 may be disposed on the second redistribution oxide layer 236.

The second dummy pattern layer 240 may be disposed on the second interlayer insulating layer 220. The lower surface of the second dummy pattern layer 240 may form the same plane with the lower surface of the second insulating structure 230. The second dummy pattern layer 240 may overlap with at least a part of the region disposed between the second outer boundary 221 and the second inner boundary 231.

One side surface 240a of the second dummy pattern layer 240 may be disposed inward of the second inner boundary 231. The one side surface 240a of the second dummy pattern layer 240 may be disposed inward of the one side surface 230a of the second insulating structure 230. The other side surface 240b of the second dummy pattern layer 240 may be disposed outward of the second inner boundary 231. The other side surface 240b of the second dummy pattern layer 240 may be disposed outward of the one side surface 230a of the second insulating structure 230.

The second barrier structure 250 may be disposed on the second dummy pattern layer 240. In an embodiment, the second barrier structure 250 may overlap with the second dummy pattern layer 240. The second barrier structure 250 may be disposed on the one side surface 230a of the second insulating structure 230. The second barrier structure 250 may be disposed between the one side surface 230a of the second insulating structure 230 and the other side surface 240b of the second dummy pattern layer 240. The lower surface of the second barrier structure 250 may be spaced apart more from the second substrate 201 than the lower surface of the second insulating structure 230.

The second barrier structure 250 may include a second inner barrier layer 251 and a second outer barrier layer 252. The uppermost surface of the second inner barrier layer 251 may be disposed closer to the second substrate 201 than the upper surface of the second insulating structure 230.

Although FIG. 3 illustrates that the second barrier structure 250 includes a second middle part 250m extending parallel to the first direction FD and second edge part 250e extending parallel to the third direction VD, however, the embodiments are not limited thereto, and the extending direction or directions of the second barrier structure 250 may be changed in various ways.

The second outer barrier layer 252 may overlap with the second inner barrier layer 251. The lower surface of the second passivation layer 232 may be disposed closer to the second substrate 201 than the lower surface of the second inner barrier layer 251. The lower surface of the second inner barrier layer 251 may be disposed between the upper surface of the second passivation layer 232 and the lower surface of the second passivation layer 232.

The distance from the uppermost surface of the second inner barrier layer 251 to the second substrate 201 in the vertical direction may be larger than the distance from the uppermost surface of the second guard ring 210 to the second substrate 201 in the vertical direction.

The second outer barrier layer 252 may be disposed outward of the second inner barrier layer 251 from the one side surface 230a of the second insulating structure 230. The second outer barrier layer 252 may be disposed on the second inner barrier layer 251.

The second outer barrier layer 252 may completely cover one of the side surfaces of the second inner barrier layer 251. In an embodiment, one of the side surfaces of the second inner barrier layer 251 may be spaced apart from the one side surface 230a of the second insulating structure 230. One of the side surfaces of the second inner barrier layer 251 may be disposed between the one side surface 230a of the second insulating structure 230 and the side surface of the second redistribution pattern layer 260. In an embodiment, one of the side surfaces of the second inner barrier layer 251 may be disposed between the second outer boundary 221 and the second inner boundary 231.

Although not illustrated in FIG. 3, in an embodiment, the second outer barrier layer 252 may extend in the third direction VD to cover the uppermost surface of the second inner barrier layer 251.

The second inner barrier layer 251 may include substantially the same material as the first inner barrier layer 151. The second outer barrier layer 252 may include substantially the same material as the second inner barrier layer 251.

The second redistribution pattern layer 260 may be disposed on the second barrier structure 250. The second redistribution pattern layer 260 may cover the second barrier structure 250. The second redistribution pattern layer 260 may be spaced apart from the second inner barrier layer 251.

Although not illustrated in FIG. 3, in an embodiment, the second redistribution pattern layer 260 may extend in the third direction VD to cover the uppermost surface of the second barrier structure 250. Although FIG. 3 illustrates that the second redistribution pattern layer 260 has a middle part extending in the first direction FD, the embodiments are not limited thereto, and the extending direction of the second redistribution pattern layer 260 may be changed in various ways.

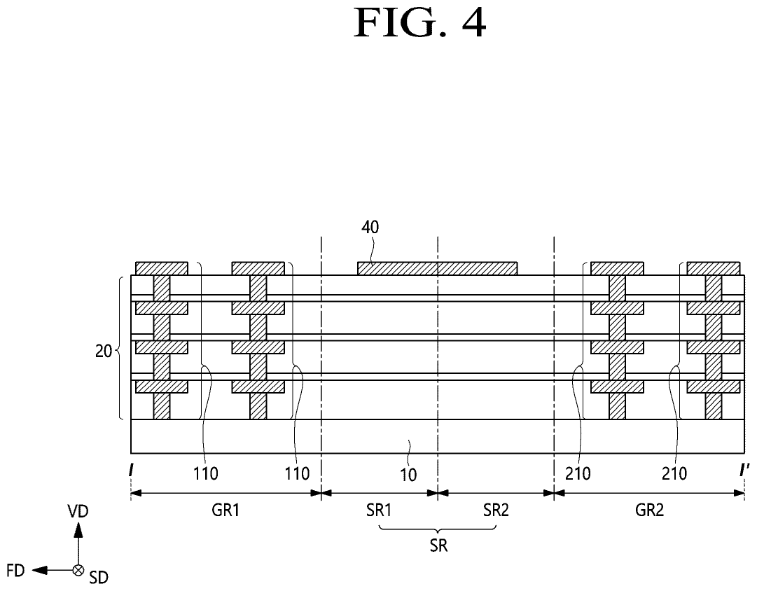

FIG. 4 to FIG. 11 are views illustrating of a method of forming a semiconductor device according to an embodiment disclosed in FIG. 3.

Referring to FIG. 4, guard rings 110 and 210 and an interlayer insulating layer 20 may be formed on a substrate 10. The first guard ring 110 may be disposed in a first guard ring region GR1. The second guard ring 210 may be disposed in a second guard ring region GR2.

A dummy pattern layer 40 may be formed on the interlayer insulating layer 20. The dummy pattern layer 40 may be disposed in a scribe lane region SR. In an embodiment, the dummy pattern layer 40 may include aluminum (Al).

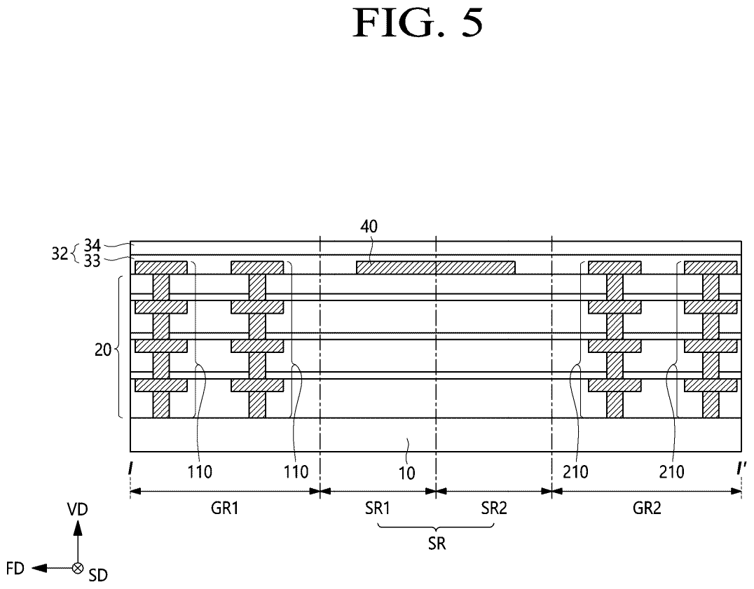

Referring to FIG. 5, a passivation layer 32 may be formed on the interlayer insulating layer 20. The passivation layer 32 may control moisture penetration, etc. during a subsequent process. The passivation layer 32 may include a passivation oxide layer 33 and a passivation nitride layer 34. The passivation nitride layer 34 may be disposed on the passivation oxide layer 33. In an embodiment, the passivation oxide layer 33 may include high density plasma oxide.

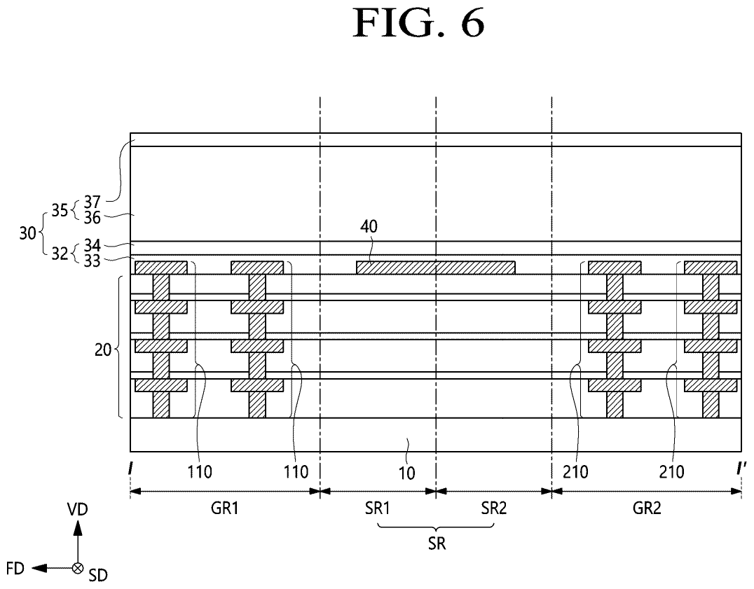

Referring to FIG. 6, a redistribution insulating layer 35 may be formed on the passivation layer 32. The redistribution insulating layer 35 may include a redistribution oxide layer 36 and a redistribution nitride layer 37. The redistribution nitride layer 37 may be disposed on the redistribution oxide layer 36. An insulating structure 30 may be formed which includes the passivation layer 32 and the redistribution insulating layer 35.

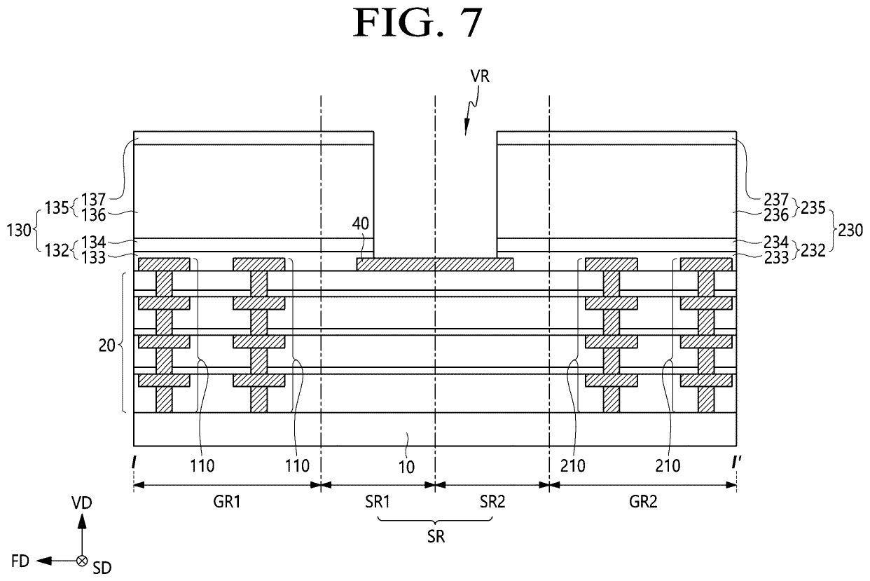

Referring to FIG. 7, a redistribution via region VR may be formed in the scribe lane region SR. The redistribution via region VR may be formed to penetrate an upper part of the insulating structure 30. The redistribution via region VR may be formed through anisotropic etching to expose an upper surface of the dummy pattern layer 40. In an embodiment, the redistribution via region VR may have a bar shape, however, the embodiments are not limited thereto. The shape of the redistribution via region VR may be changed in various ways. The lower surface of the redistribution via region VR may contact a part of the upper surface of the dummy pattern layer 40. As the redistribution via region VR is formed, a first insulating structure 130 and a second insulating structure 230 may be formed.

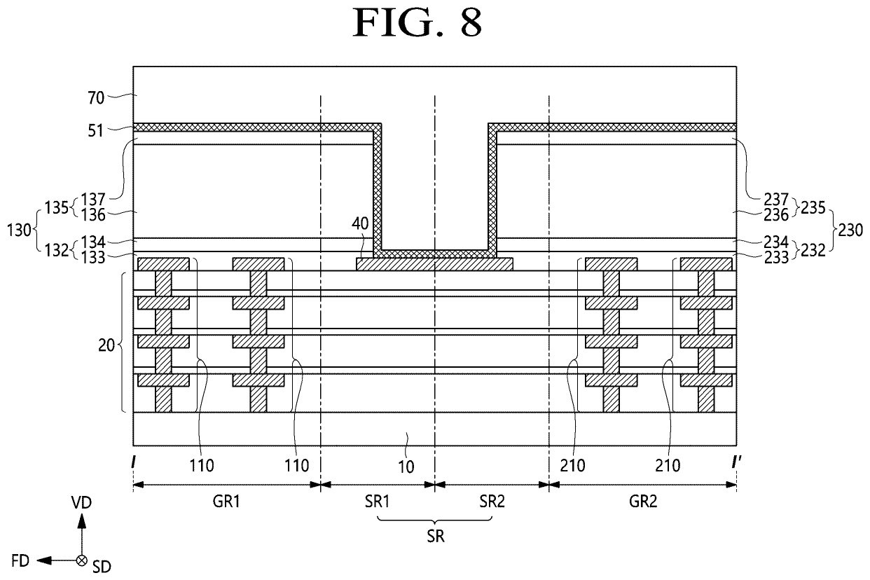

Referring to FIG. 8, an inner barrier layer 51 may be formed on the upper surface and the side surface of the first insulating structure 130, the upper surface and the side surface of the second insulating structure 230, and the upper surface of the dummy pattern layer 40. The inner barrier layer 51 may be formed using a film forming technique with excellent step coverage property, such as chemical vapor deposition (CVD), physical vapor deposition (PVD) or atomic layer deposition (ALD). The inner barrier layer 51 may include a conductive metal nitride such as titanium nitride (TiN), tantalum nitride (TaN) and tungsten nitride (WN). In an embodiment, the inner barrier layer 51 may include titanium nitride (TiN).

A dummy oxide layer 70 may be formed on the inner barrier layer 51. Referring to FIG. 8, the dummy oxide layer 70 may fill the interior of the redistribution via region VR.

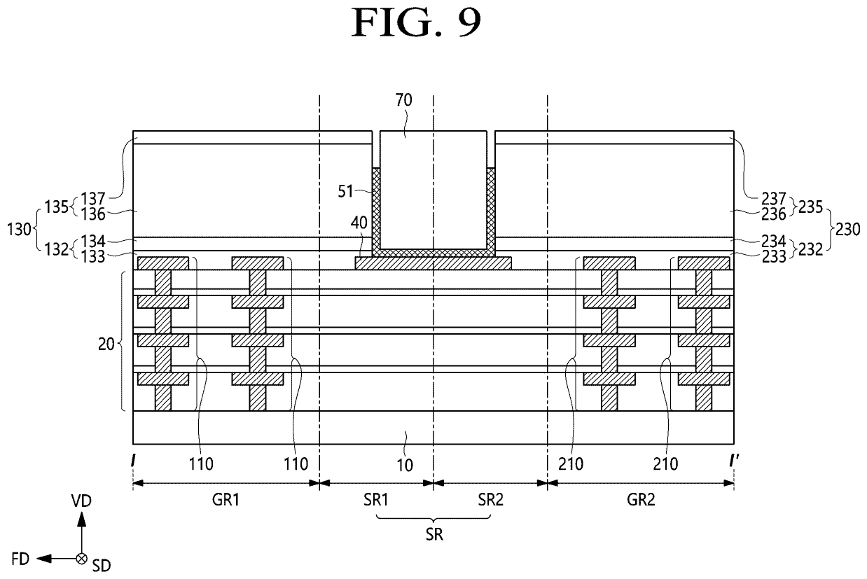

Referring to FIG. 9, the dummy oxide layer 70 may be etched to expose parts of the upper surface of the inner barrier layer 51. Redistribution nitride layers 137 and 237 may be utilized as an etch barrier to form the inner barrier layer 51 on the sidewalls of the redistribution via region VR.

After the parts of the upper surface of the inner barrier layer 51 are exposed, an etching process may be performed on the inner barrier layer 51. The upper surface of the first insulating structure 130 and the upper surface of the second insulating structure 230 may be exposed. The upper surface of the first insulating structure 130, the upper surface of the second insulating structure 230 and the upper surface of the dummy oxide layer 70 may form the same or substantially the same plane. The uppermost surface of the inner barrier layer 51 may be disposed closer to the substrate 10 than the upper surface of the first insulating structure 130 and the upper surface of the second insulating structure 230.

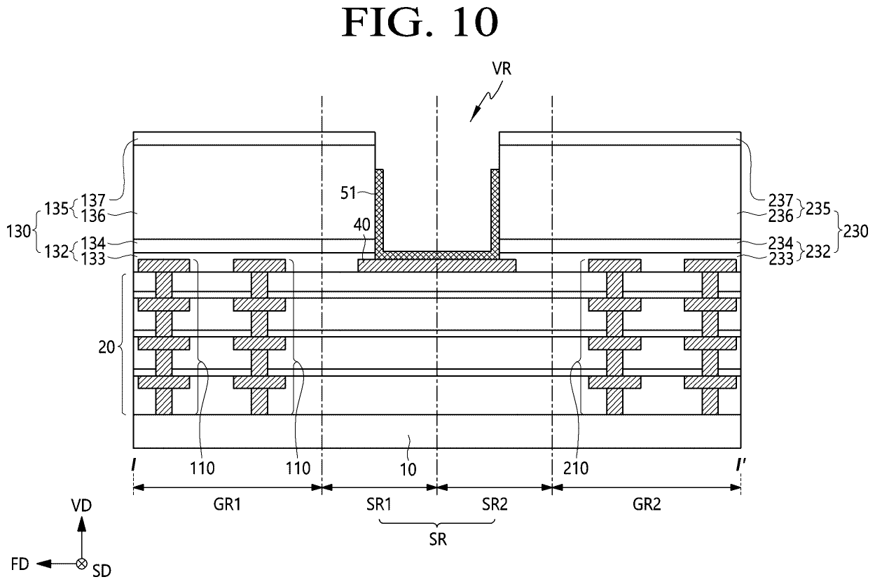

Referring to FIG. 10, the dummy oxide layer 70 may be removed, for example, through an etching process. As a result, the upper surface and the side surface of the inner barrier layer 51 may be exposed. Only the inner barrier layer 51 may be disposed in the redistribution via region VR.

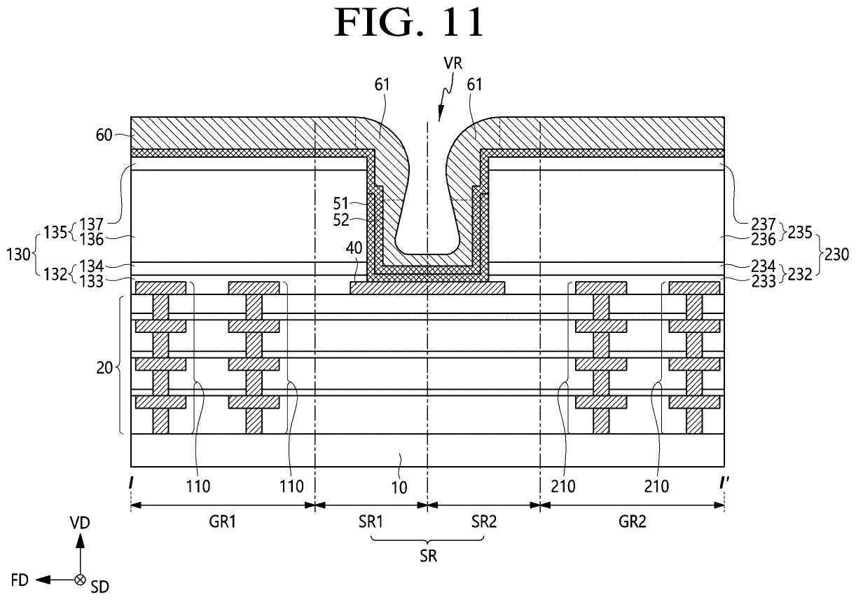

Referring to FIG. 11, an outer barrier layer 52 may be formed to cover the upper surface and a part of the side surface of the first insulating structure 130, the upper surface and a part of the side surface of the second insulating structure 230, and the upper surface and the side surface of the inner barrier layer 51. The outer barrier layer 52 may be formed in the same method as the inner barrier layer 51. In an embodiment, the outer barrier layer 52 may be formed to conformally cover the inner barrier layer 51. In an embodiment, the outer barrier layer 52 may include the same material as the inner barrier layer 51.

A redistribution material 60 may be deposited on the outer barrier layer 52. As the redistribution material 60 is deposited, an overhang 61 may be formed. The redistribution material 60 may include a conductive metal material such as copper (Cu) or aluminum (Al). In an embodiment, the redistribution material 60 may include aluminum (Al).

Because the outer barrier layer 52 and the redistribution material 60 are formed after only the inner barrier layer 51 is disposed in the redistribution via region VR, it is possible to compensate for the thin deposition of the redistribution material 60 at the lower end of the redistribution via region VR, thereby reducing the occurrence of a crack, etc. at the lower end of the redistribution via region VR.

Because the deposition thickness of the redistribution material 60 decreases, an overhang becomes smaller, which makes it possible to reduce the width of the redistribution via region VR. Accordingly, cuttability may be improved during a subsequent process, and when recognizing the redistribution alignment key RK, the recognition space (redistribution via space) of the redistribution via region VR may be secured.

Referring again to FIG. 3, an etching process may be performed on the redistribution material 60. An etching process on the outer barrier layer 52 may be performed. A part of the redistribution conductive material 60 may be removed. A part of the outer barrier layer 52 may be removed. By etching the redistribution material 60, redistribution pattern layers 160 and 260 may be formed.

Although not illustrated, a dummy insulating layer may be formed. The dummy insulating layer may cover the upper surfaces and parts of the side surfaces of the insulating structures 130 and 230, the uppermost surfaces of barrier structures 150 and 250 and the redistribution pattern layers 160 and 260. In an embodiment, the dummy insulating layer may include polyimide isoindro quirazorindione (PIQ).

Although detailed embodiments of the present disclosure have been disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A semiconductor device comprising:
a substrate including a chip region and a scribe lane region;
an insulating structure disposed on the substrate, and having one side surface in the scribe lane region;
a barrier structure including an inner barrier layer that has an uppermost surface disposed closer to the substrate than the upper surface of the insulating structure and overlaps with the one side surface of the insulating structure and an outer barrier layer on the inner barrier layer; and
a redistribution pattern layer covering the barrier structure and spaced apart from the inner barrier layer.

2. The semiconductor device according to claim 1, wherein the outer barrier layer completely covers a side surface among the side surfaces of the inner barrier layer that is spaced apart from the one side surface of the insulating structure and is disposed between the one side surface of the insulating structure and the side surface of the redistribution pattern layer.

3. The semiconductor device according to claim 1, wherein the outer barrier layer includes the same material as the inner barrier layer.

4. The semiconductor device according to claim 1, further comprising
a dummy pattern layer having a lower surface that forms the same plane with the lower surface of the insulating structure, one side surface that is disposed inward of the one side surface of the insulating structure, and the other side surface that is disposed outward of the one side surface of the insulating structure.

5. The semiconductor device according to claim 4, wherein the barrier structure overlaps with the dummy pattern layer.

6. The semiconductor device according to claim 4, wherein the barrier structure is disposed between the one side surface of the insulating structure and the other side surface of the dummy pattern layer.

7. The semiconductor device according to claim 1, wherein
the insulating structure includes a passivation layer, and
wherein the lower surface of the passivation layer is disposed closer to the substrate than the lower surface of the inner barrier layer.

8. The semiconductor device according to claim 7, wherein the lower surface of the inner barrier layer is disposed between the upper surface of the passivation layer and the lower surface of the passivation layer.

9. The semiconductor device according to claim 7, wherein the passivation layer includes high density plasma oxide, nitride, or a combination thereof.

10. The semiconductor device according to claim 1, further comprising
a guard ring disposed inward of the one side surface of the insulating structure,
wherein the distance from the uppermost surface of the inner barrier layer to the substrate in a vertical direction is larger than the distance from the uppermost surface of the guard ring to the substrate in the vertical direction.

11. A semiconductor device comprising:
a substrate;
an interlayer insulating layer disposed on the substrate, and including an outer boundary;
an insulating structure disposed on the interlayer insulating layer, and including an inner boundary that is disposed inward of the outer boundary;
a barrier structure including an inner barrier layer that has an uppermost surface disposed closer to the substrate than the upper surface of the insulating structure and overlaps with one side surface of the insulating structure and an outer barrier layer on the inner barrier layer; and
a redistribution pattern layer covering the barrier structure and spaced apart from the inner barrier layer.

12. The semiconductor device according to claim 11, wherein the outer barrier layer completely covers a side surface among the side surfaces of the inner barrier layer that is disposed between the outer boundary and the inner boundary.

13. The semiconductor device according to claim 11, wherein the outer barrier layer includes the same material as the inner barrier layer.

14. The semiconductor device according to claim 11, further comprising
a dummy pattern layer having a lower surface that forms the same plane with the lower surface of the insulating structure, overlapping at least a part of a region between the outer boundary and the inner boundary, and having one side surface that is disposed inward of the inner boundary and the other side surface that is disposed outward of the inner boundary.

15. The semiconductor device according to claim 14, wherein the barrier structure overlaps with the dummy pattern layer.

16. The semiconductor device according to claim 14, wherein the barrier structure is disposed between the inner boundary and the other side surface of the dummy pattern layer.

17. The semiconductor device according to claim 11, wherein
the insulating structure includes a passivation layer, and
wherein the lower surface of the passivation layer is disposed closer to the substrate than the lower surface of the inner barrier layer.

18. The semiconductor device according to claim 17, wherein the lower surface of the inner barrier layer is disposed between the upper surface of the passivation layer and the lower surface of the passivation layer.

19. The semiconductor device according to claim 11, further comprising
a guard ring disposed inward of the inner boundary,
wherein the distance from the uppermost surface of the inner barrier layer to the substrate in a vertical direction is larger than the distance from the uppermost surface of the guard ring to the substrate in the vertical direction.

20. A semiconductor device comprising:
an interlayer insulating layer over a substrate;
an insulating structure disposed over the interlayer insulating layer, the insulating structure comprising a redistribution insulating layer and a passivation layer;
a guard ring passing through the interlayer insulating layer and extending inside the passivation layer over a guard ring region of the substrate;
an insulating structure disposed on the substrate, and having one side surface in a scribe lane region of the substrate;
a dummy pattern layer having a lower surface that is coplanar with the lower surface of the passivation layer;
a barrier structure formed over the dummy pattern layer, and having a middle part extending parallel to the dummy pattern in a first direction and a edge part extending vertically to the dummy pattern layer, and
a redistribution pattern layer covering the barrier structure.
